(19) United States
(12) Patent Application Publication
(10) Pub. No.: US 2015/0041980 A1
(43) Pub. Date: Feb. 12, 2015

(54) Semiconductor Package with Reduced Thickness

(71) Applicant: Amkor Technology, Inc., Chandler, AZ (US)

(72) Inventors: Seo Yeon Ahn, Gyeonggi-do (KR); Pil Je Sung, Seoul (KR); Doo Hyun Park, Gyeonggi-do (KR); Jong Sik Paek, Incheon (KR); Young Rae Kim, Gyeonggi-do (KR); Hui Tae Kim, Gyeonggi-do (KR); Yong Song, Seoul (KR); Seok Woo Yun, Seoul (KR)

(21) Appl. No.: 14/452,933

(22) Filed: Aug. 6, 2014

(30) Foreign Application Priority Data
Aug. 6, 2013 (KR) 00932440085629

(51) Int. Cl. H01L 23/00; H01L 21/304

(52) U.S. Cl. CPC H01L 24/97; H01L 24/83; H01L 21/304; H01L 24/17; H01L 24/32; H01L 2224/80815
USPC 257/738; 438/107

(57) ABSTRACT

A method for forming a reduced thickness semiconductor package is disclosed and may include providing a first die with an active layer, a through-silicon via (TSV), and a pattern and an under bump metal (UBM) in a dielectric layer on the active layer. A carrier may be bonded to the dielectric layer and the UBM. The first die may be thinned to expose the TSV. A bump pad may be formed on the exposed TSV and a second die may be bonded to the bump pad. The first die, the second die, and an outer surface of the dielectric layer may be encapsulated utilizing a first encapsulant. The carrier may be removed from the dielectric layer and the UBM, and a solder ball may be formed on the UBM. A groove may be formed through the dielectric layer and into the first die.

### CROSS-REFERENCE TO RELATED APPLICATIONS

The present application makes reference to, claims priority to, and claims the benefit of Korean Patent Application No. 10-2013-00932440085629, filed on Aug. 6, 2013, the contents of which are hereby incorporated herein by reference, in their entirety.

### FIELD

Certain embodiments of the disclosure relate to semiconductor chip packaging. More specifically, certain embodiments of the disclosure relate to a semiconductor package with reduced thickness.

### BACKGROUND

As there is increasing demand for highly functional electronic products along with miniaturization of the electronic products, various techniques for providing high-capacity semiconductor modules are being researched and developed. One of the methods for providing high-capacity semiconductor modules is to increase the capacity of a memory chip, that is, to highly integrate memory chips, which can be achieved by integrating as many cells as possible into a limited semiconductor chip space.

However, the high integration of memory chips requires highly sophisticated techniques and a substantial amount of time for development. Therefore, another method for providing high-capacity semiconductor modules has been proposed, in which semiconductor dies are stacked. In addition, a method for fabricating a wafer level package having a plurality of semiconductor dies has been proposed as a next-generation package.

Further limitations and disadvantages of conventional and traditional approaches will become apparent to one of skill in the art, through comparison of such systems with the present disclosure as set forth in the remainder of the present application with reference to the drawings.

### BRIEF SUMMARY

A semiconductor package with reduced thickness substantially as shown in and/or described in connection with at least one of the figures, as set forth more completely in the claims.

Various advantages, aspects and novel features of the present disclosure, as well as details of various embodiments thereof, will be more fully understood from the following description and drawings.

### BRIEF DESCRIPTION OF SEVERAL VIEWS OF THE DRAWINGS

FIG. 1 is a flowchart of a method for fabricating a semiconductor package according to an embodiment of the present disclosure.

FIGS. 2A to 2M are partial cross-sectional views sequentially illustrating the method for fabricating a semiconductor package shown in FIG. 1.

FIG. 3A is a cross-sectional view of a semiconductor package according to an embodiment of the present disclosure.

FIG. 3B is an enlarged view of a portion of FIG. 3A, in accordance with an example embodiment of the present disclosure.

FIG. 4 is a flowchart of a method for fabricating a semiconductor package according to another embodiment of the present disclosure.

FIGS. 5A to 5J are partial cross-sectional views sequentially illustrating the method for fabricating a semiconductor package shown in FIG. 4.

### DETAILED DESCRIPTION

Certain aspects of the disclosure may be found in providing a first semiconductor die with an active layer, a through-silicon via (TSV), and a pattern and an under bump metal (UBM) in a dielectric layer on the active layer. A carrier may be bonded to the dielectric layer and the UBM. The first semiconductor die may be thinned to expose the TSV at a second surface of the first semiconductor die. A bump pad may be formed on the exposed TSV and a second semiconductor die may be bonded to the bump pad. The first semiconductor die, the second semiconductor die, and an outer surface of the dielectric layer may be encapsulated utilizing a first encapsulant. The carrier may be removed from the dielectric layer and the UBM, and a solder ball may be formed on the UBM. A groove may be formed through the dielectric layer and into the first semiconductor die. The groove may be filled and the dielectric layer and a portion of the solder ball may be encapsulated utilizing a second encapsulant. The first semiconductor die may be separated into a plurality of units by sawing through the groove and the first and second encapsulants. The first encapsulant may be thinned such that it may be coplanar with a surface of the second semiconductor die. The first encapsulant may be thinned using a grinding process. The semiconductor package may have a thickness of 580 μm or less. The semiconductor die may be bonded to the bump pad using a non-conductive film in a thermal compression process. The semiconductor die may be bonded to the bump pad using a reflow process. The pattern may comprise a redistribution layer (RDL). The groove may be formed using a laser drilling process.

Various aspects of the present disclosure may be embodied in many different forms and should not be construed as being limited to the example embodiments set forth herein. Rather, these example embodiments of the disclosure are provided so that this disclosure will be thorough and complete and will fully convey various aspects of the disclosure to those skilled in the art.

In the drawings, the thickness of layers and regions are exaggerated for clarity. Here, like reference numerals refer to like elements throughout. As used herein, the term “and/or” includes any and all combinations of one or more of the associated listed items. In addition, the terminology used herein is for the purpose of describing particular embodiments only and is not intended to be limiting of the disclosure. As used herein, the singular forms are intended to include the plural forms as well, unless the context clearly indicates otherwise. It will be further understood that the terms “comprises” and/or “comprising,” when used in this specification, specify the presence of stated features, numbers, steps, operations, elements, and/or components, but do not preclude the presence or addition of one or more other features, numbers, steps, operations, elements, components, and/or groups thereof.

It will be understood that, although the terms first, second, etc. may be used herein to describe various members, elements, regions, layers and/or sections, these members, elements, regions, layers and/or sections should not be limited by these terms. These terms are only used to distinguish one member, element, region, layer and/or section from another. Thus, for example, a first member, a first element, a first region, a first layer and/or a first section discussed below could be termed a second member, a second element, a second region, a second layer and/or a second section without departing from the teachings of the present disclosure.

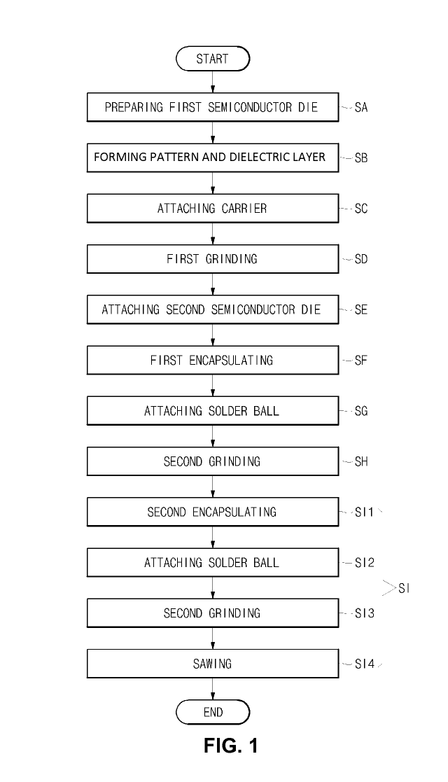

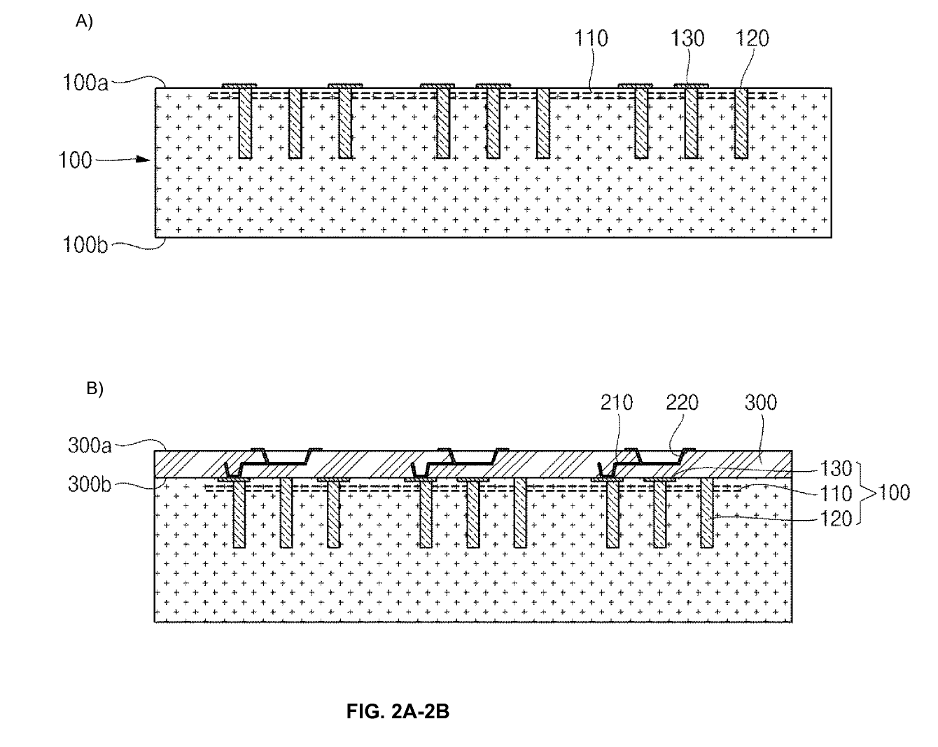

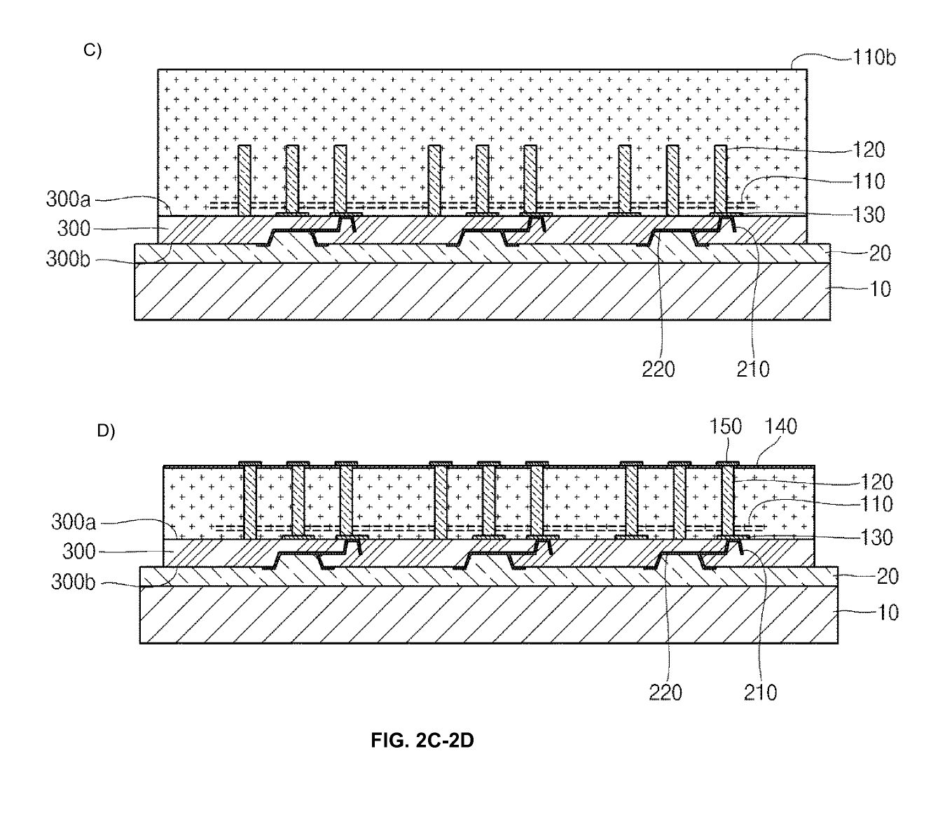

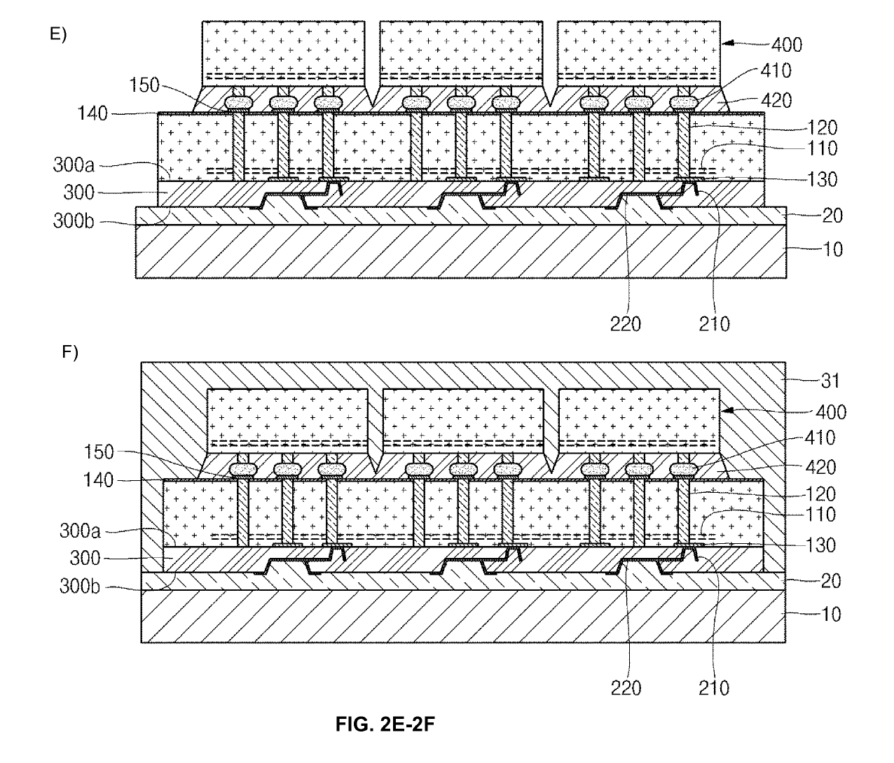

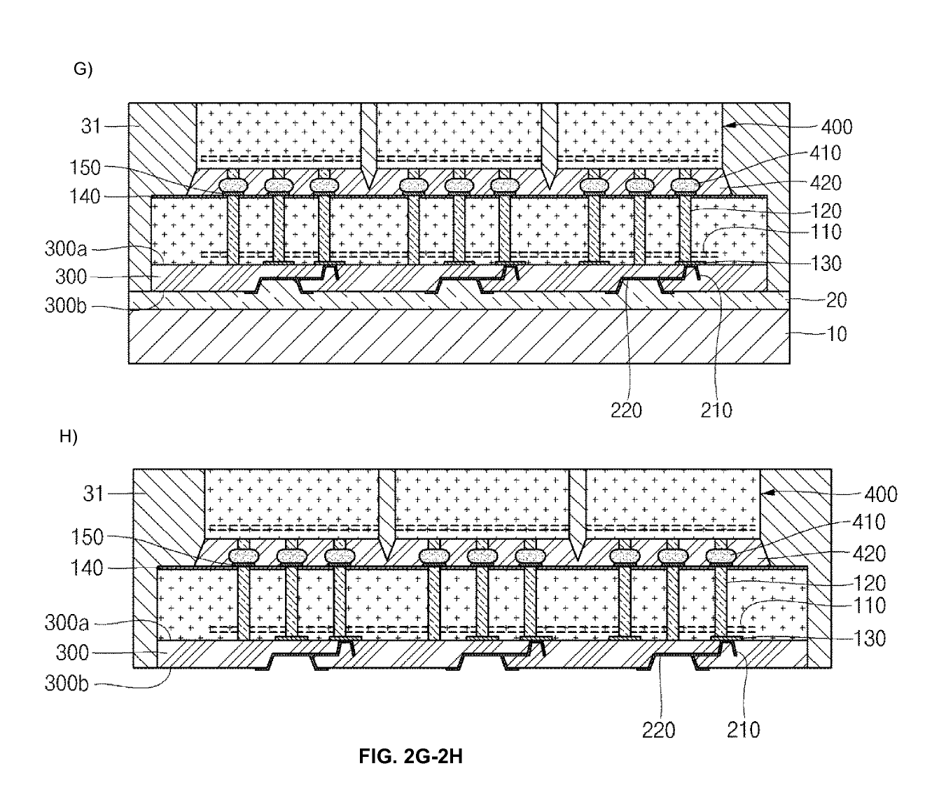

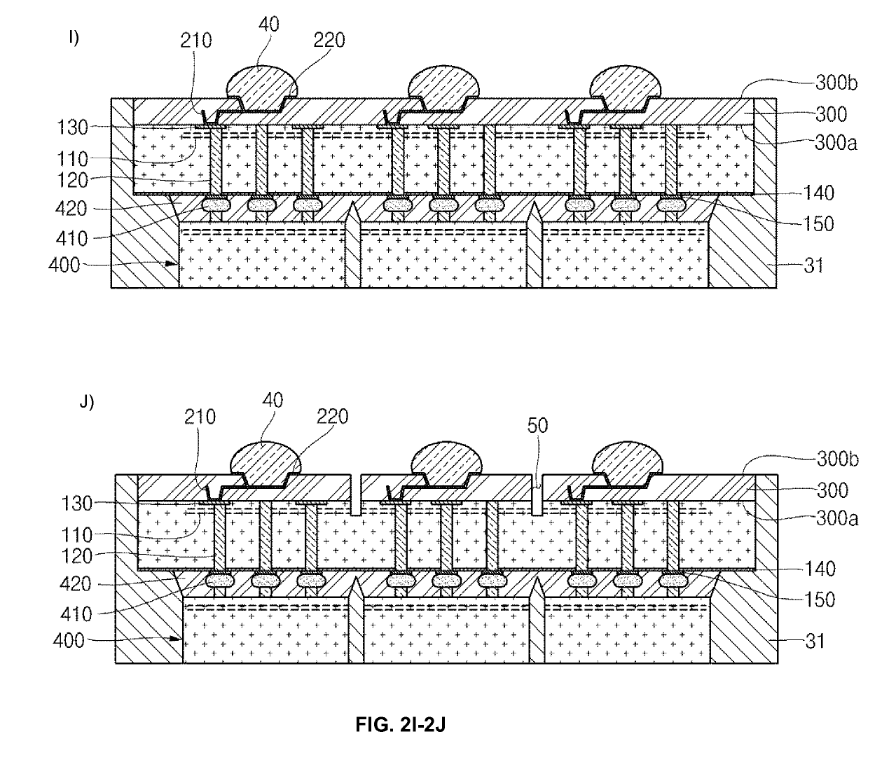

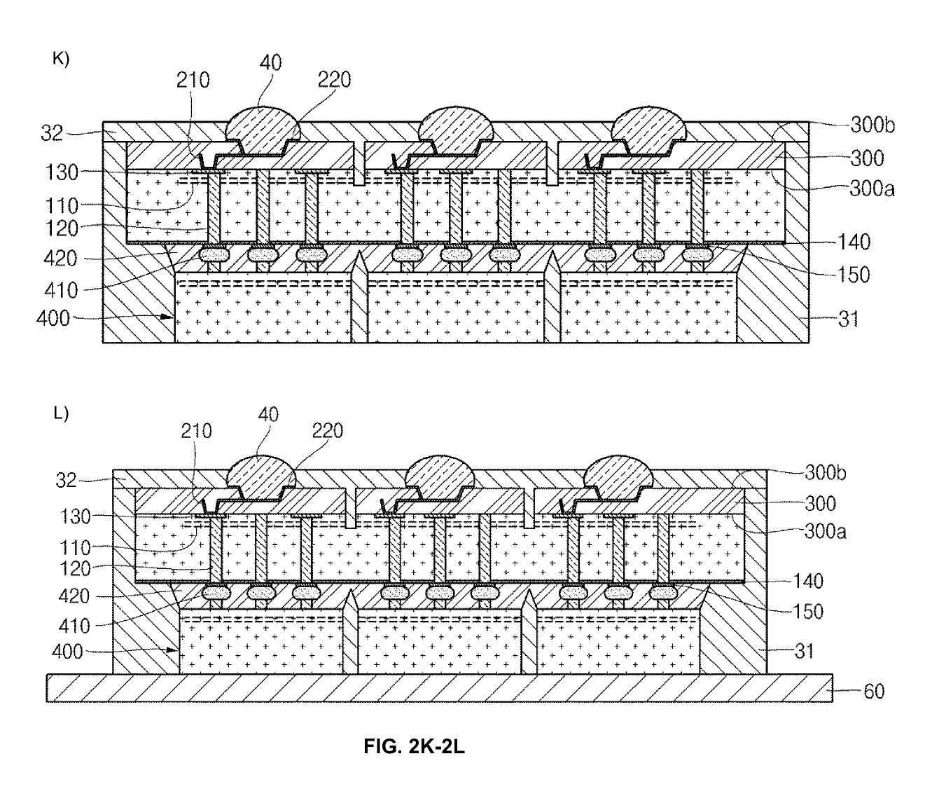

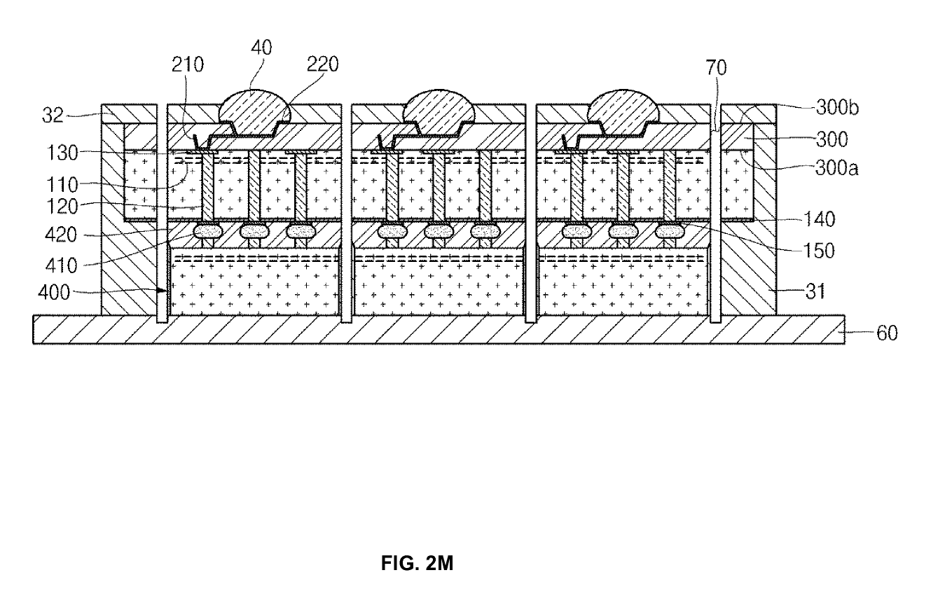

FIG. 1 is a flowchart of a method for fabricating a semiconductor package according to an embodiment of the present disclosure and FIGS. 2A to 2M are partially cross-sectional views sequentially illustrating the method for fabricating a semiconductor package shown in FIG. 1.

Referring to FIG. 1, the method for fabricating a semiconductor package according to an embodiment of the present disclosure includes (SA) preparing a first semiconductor die, (SB) forming a pattern and a dielectric layer, (SC) attaching the dielectric layer to a carrier, (SD) first grinding, (SE) attaching a second semiconductor die to the first semiconductor die, (SF) first encapsulating, (SG) attaching a solder ball, (SH) second grinding, and (SI) sawing.

As illustrated in FIG. 2A, in step (SA), a first semiconductor die 100 is prepared, the first semiconductor die 100 including an active layer 110, at least one through silicon via (TSV) 120 electrically connected to the active layer 110 and a bond pad 130 electrically connected to the TSV 120.

The first semiconductor die 100 has a first surface 100a that is substantially planar, and a second surface 100b that is formed opposite to the first surface 100a and is substantially planar.

The active layer 110 is formed around the first surface 100a of the first semiconductor die 100. A plurality of device layers are formed by patterning a circuit to be formed on a thin film including at least one of silicon (Si), gallium arsenic (GaAs) for example, and depositing a copper (Cu) or aluminum (Al) wiring. In order to form the device layers, a device isolation layer and an interlayer dielectric layer, which are made from an insulting material, may further be formed.

The active layer 110 may be an integrated circuit (IC) including an active device, such as a transistor, or an integrated passive device (IPD) having a capacitor, a resistor, etc., integrated therein, but aspects of the present disclosure are not limited thereto. Meanwhile, for ease of description of the present disclosure, two active layers 110 are illustrated. However, multiple active layers may also be provided in an embodiment of the present disclosure.

The TSV 120 may be formed by filling a conductive material into a throughhole to be formed to a predetermined depth from the first surface 100a of the first semiconductor die 100.

For example, the throughhole of the TSV 120 may be formed by laser drilling or chemical etching, but aspects of the present disclosure are not limited thereto.

The TSV 120 may be formed of at least one conductive material comprising copper (Cu), gold (Au), silver (Ag), or aluminum (Al) for example, but aspects of the present disclosure are not limited thereto. In addition, the TSV 120 may be formed by a process comprising physical vapor deposition (PVD), chemical vapor deposition (CVD), electroplating or electroless plating, for example, but aspects of the present disclosure are not limited thereto. Although not shown, an inner wall of the TSV 120 may be filled by an insulating layer to electrically insulate the TSV 120 and the first semiconductor die 100.

The bond pad 130 may be exposed to the first surface 100a of the first semiconductor die 100.

A passivation layer (not shown) to be described later may be formed on the first surface 100a of the first semiconductor die 100. For example, the passivation layer may protect the first surface 100a of the first semiconductor die 100 and the bond pad 130 may be exposed to the outside of the passivation layer.

The bond pad 130 may be electrically connected to the active layer 110 through the TSV 120. The bond pad 130 may comprise copper (Cu), aluminum (Al) or equivalents thereof, for example, but aspects of the present disclosure are not limited thereto. In addition, the bond pad 130 may be formed by sputtering, vacuum deposition, or photolithography, but aspects of the present disclosure are not limited thereto.

As illustrated in FIG. 2B, in step (SB), a pattern 210 and a dielectric layer 300 protecting the pattern 210 may be formed on the first surface 100a of the first semiconductor die 100.

The pattern 210 may be electrically connected to the TSV 120 through the bond pad 130 and electrically connected to the active layer 110.

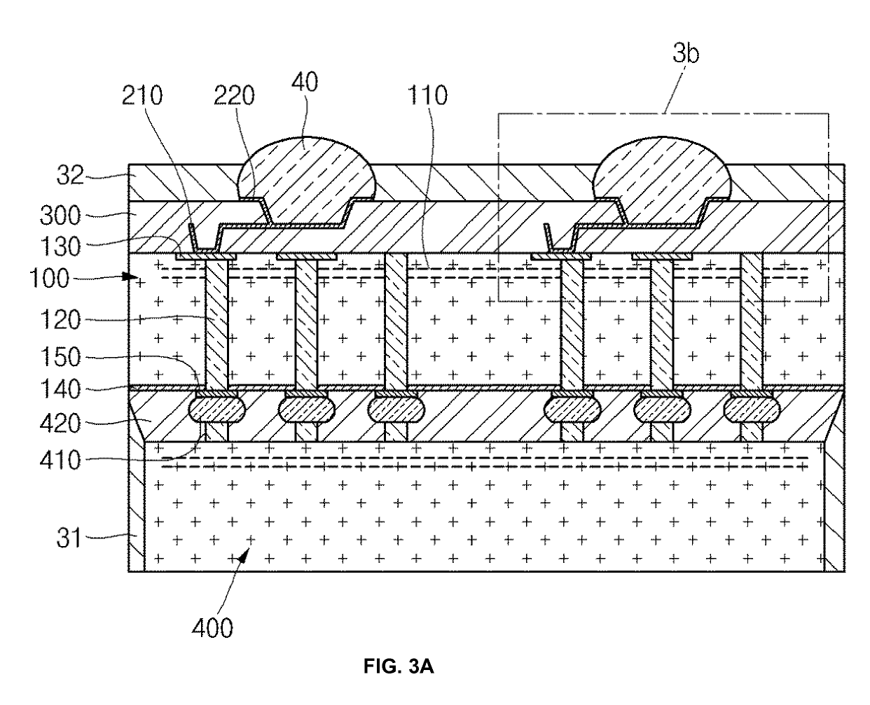

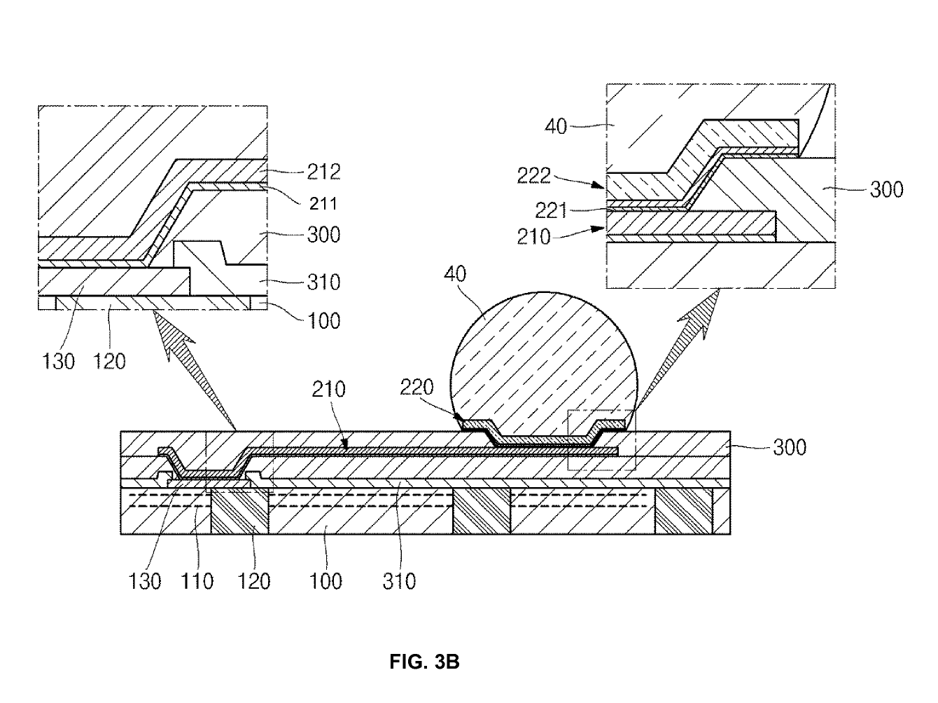

The pattern 220 may comprise a redistribution layer (RDL) and may be made from copper (Cu), gold (Au), silver (Ag), nickel (Ni) or equivalents thereof, for example, but aspects of the present disclosure are not limited thereto. In addition, the pattern 210 will later be described in more detail with reference to FIG. 3B.

The dielectric layer 300 may be formed on one surface of the passivation layer and has a first surface 300a and a second surface 300b. The dielectric layer 300 may protect the pattern 210 and may comprise polyimide (PI), benzocyclobutene (BCB), polybenzoxazole (PBO), or equivalents thereof, for example, but aspects of the present disclosure are not limited thereto.

An under bump metallurgy (UBM) 220 electrically connected to the pattern 210 may be exposed to the outside of the dielectric layer 300. For example, the UBM 220 may comprise copper (Cu), gold (Au), silver (Ag), nickel (Ni) or equivalents thereof, for example, but aspects of the present disclosure are not limited thereto. The UBM 220 will later be described in more detail with reference to FIG. 3B.

As illustrated in FIG. 2C, in step (SC), the carrier 10 may be attached and fixed to one surface of the dielectric layer 300. An adhesive layer 20 having an adhesive component may be formed between the one surface of the dielectric layer 300 and the carrier 10.

As illustrated in FIG. 2D, in step (SD), unnecessary portions of the first semiconductor die 100 may be removed by grinding the second surface 100b of the first semiconductor die 100 by a predetermined thickness, thereby allowing the TSV 120 to be exposed. The grinding may be performed using, for example, a diamond grinder, but aspects of the present disclosure are not limited thereto.

In step (SD), an insulating layer 140 may be formed on the second surface 100b of the first semiconductor die 100 after the grinding.

In addition, the bump pad 150, which may be connected to a conductive bump to be described later, is formed on the exposed surface of the TSV 120 to be exposed from the insulating layer 140. The bump pad 150 may, for example, be made from a material comprising tin-lead (Sn—Pb), tin-lead-silver (Sn—Pb—Ag), tin-lead-bismuth (Sn—Pb—Bi), tin-copper (Sn—Cu), tin-silver (Sn—Ag), tin-bismuth (Sn—Bi), tin-copper-silver (Sn—Ag—Cu), tin-silver-bismuth (Sn—Ag—Bi), tin-zinc (Sn—Zn) or equivalents thereof, but aspects of the present disclosure are not limited thereto.

As illustrated in FIG. 2E, in step (SE), a second semiconductor die 400 including an active layer may be attached to the second surface 100b of the first semiconductor die 100. The second semiconductor die 400 may comprise a first surface that is substantially planar, and a second surface opposite to the first surface that is substantially planar.

The second semiconductor die 400 and the bump pad 150 of the first semiconductor die 100 may be electrically connected by the conductive bump 410 interposed there between. The conductive bump 410 may be made from one or more materials comprising metals such as lead/tin (Pb/Sn) or leadless Sn, and/or equivalents thereof, but aspects of the present disclosure are not limited thereto.

The step (SE) may, for example, be performed by a reflow process or a thermal compression process.

During the reflow process, the conductive bump 410 and the second semiconductor die 400 may be arranged on the bump pad 150 of the first semiconductor die 100 to then passed through a chamber including a conveyor-like moving unit. A temperature high enough to melt the conductive bump 410 may be applied to an entrance of the chamber, and then the temperature slowly lowered to fuse and cure the conductive bump 410. An underfill 420 may be filled between the first semiconductor die 100 and the second semiconductor die 400, followed by curing. The underfill 420 may, for example, protect the conductive bump 410 from external factors, such as mechanical impacts or corrosion, which may occur during the manufacture of the semiconductor package. The underfill 420 may, for example, be made from one or more materials comprising an epoxy thermocurable material, polyimide, polyurethane, a polymeric material, filled epoxy, a filled thermoplastic material, a filled thermocurable material, filled polyimide, filled polyurethane, a filled polymeric material, fluxed underfill, and/or equivalents thereof, but aspects of the present disclosure are not limited thereto.

During the thermal compression process, a nonconductive film (NCF) may be attached to the second semiconductor die 400, and the conductive bump 410 and the second semiconductor die 400 may then be arranged on the bump pad 150 of the first semiconductor die 100. Thereafter, a predetermined pressure may be applied to the second semiconductor die 400 at a predetermined temperature or higher to fuse and cure the conductive bump 410. In order to lower a working temperature and to reduce a working time, ultrasonic waves may be employed with the thermal compression process.

As illustrated in FIG. 2F, in step (SF), outer surfaces of the first semiconductor die 100, the dielectric layer 300 and the second semiconductor die 400 may be first encapsulated using a first encapsulant 31.

The first encapsulant 31 may encapsulate the first semiconductor die 100, the dielectric layer 300 and the second semiconductor die 400, thereby protecting the same from external impacts or oxidation. The first encapsulant 31 may comprise one or more materials comprising an epoxy compound performing encapsulation using a mold, a liquid encapsulant member performing encapsulation using a dispenser, and/or equivalents thereof, but aspects of the present disclosure are not limited thereto.

As illustrated in FIG. 2G, in step (SH), the first encapsulant 31 encapsulating the second surface of the second semiconductor die 400 may be removed to expose the second surface of the second semiconductor die 400. The second grinding (SH) may be performed in a similar manner to the first grinding (SE).

As illustrated in FIGS. 2H and 2I, in step (SG), after removing the carrier 10 and the adhesive layer 20, the solder ball 40 may be attached to the UBM 220.

The solder ball 40 may be electrically connected to the UBM 220 and electrically connected to the bond pad 130 through the pattern 210. For example, the semiconductor package may transmit/receive signals to/from an external device through the solder ball 40. The solder ball 40 may, for example, be formed using substantially the same material as the conductive bump 410 in substantially the same manner as the conductive bump 410. The solder ball 40 may be formed to have a larger diameter than the conductive bump 410, but aspects of the present disclosure are not limited thereto.

Next, the sawing (SI) will be described in greater detail with reference to FIGS. 2J to 2M.

The sawing (SI) may, for example, comprise laser drilling (SI1), second encapsulating (SI2), mounting (SI3) and sawing (SI4).

As illustrated in FIG. 2J, in the laser drilling step (SI1), a groove 50, or laser drilling region, may be formed in a sawing section of the first surface 300a of the dielectric layer 300 to reach a predetermined depth or thickness, which is for the purpose of preventing cracks produced due to shock during the sawing process, which will later be described, from propagating. For example, the groove 50 may be formed by laser beams irradiated from a laser drilling device (not shown). The groove 50 may, for example, be formed in a continuous line.

As illustrated in FIG. 2K, in second encapsulating step (SI2), second encapsulating may be performed using a second encapsulant 32 to protect the first surface 300a of the dielectric layer 300. The laser drilling region 50 may be encapsulated by the second encapsulant 32. However, since the solder ball 40 may be electrically connected to an external device, a portion of the solder ball 40 needs to be exposed to the outside.

Although not shown, a reference point recognizing die (not shown) may be formed in a region of the first semiconductor die 100. The pattern 210, the UBM 220, the dielectric layer 300 and the solder ball 40 might not be formed in the reference point recognizing die. In addition, one end of the reference point recognizing die might not be encapsulated by the second encapsulant 32 but exposed to the outside, like the solder ball 40. This is for the purpose of allowing sawing equipment (not shown) to recognize the one end of the reference point recognizing die as a reference coordinate point in the sawing process to be described later to secure an accurate sawing section.

As illustrated in FIG. 2L, in the mounting step (SI3), the other surface of the second semiconductor die 400 may be attached to a dicing tape 60 to fix the semiconductor package prior to the sawing process to be described later.

Thereafter, as illustrated in FIG. 2M, the sawing step (SI4) may be performed. The sawing process may be performed on the sawing section 70 using sawing equipment (e.g., a blade) to separate the second semiconductor die 400 into individual units.

Next, a semiconductor package fabricated by the method for fabricating a semiconductor package according to an embodiment of the present disclosure will be described with reference to FIGS. 3A and 3B.

FIG. 3A is a cross-sectional view of a semiconductor package according to an embodiment of the present disclosure and FIG. 3B is an enlarged view of a portion 3b of FIG. 3A.

As illustrated in FIG. 3A, the semiconductor package according to an embodiment of the present disclosure comprises a first semiconductor die 100 including an active layer 110 and at least one TSV 120 electrically connected to the active layer 110, a pattern 210 formed on a first surface of the first semiconductor die 100 and electrically connected to the TSV 120, an under bump metallurgy (UBM) 220 electrically connected to the pattern 210, a dielectric layer 300 protecting the pattern 210, a second semiconductor die 400 electrically connected to the TSV 120 and attached to the other surface of the first semiconductor die 100, a first encapsulant 31 that first encapsulates side surfaces of the second semiconductor die 400, a second encapsulant 32 that encapsulates one surface of the dielectric layer 300, and a solder ball 40 electrically connected to the second encapsulant 32 and the UBM 220 and having a portion exposed to the outside of the second encapsulant 32.

A total thickness of the semiconductor package according to an embodiment of the present disclosure may be approximately 580 μm or less.

A configuration of the semiconductor package will now be described in detail from its bottom end. A total thickness D1 of the second semiconductor die 400 and the bump pad 150 may be approximately 280 μm, a thickness D2 of the first semiconductor die 100 may be approximately 60 μm, a thickness D3 of the dielectric layer 300 protecting the pattern 210 may be approximately 40 μm, a thickness D4 of the second encapsulant 32 formed on one surface of the dielectric layer 300 may be approximately 150 μm, and a thickness D5 of one end of the solder ball 40 exposed to the outside of the second encapsulant 32 may be approximately 50 μm.

Therefore, in the semiconductor package according to an embodiment of the present disclosure, heat generated from the first semiconductor die 100 may be easily emitted to the outside through the dielectric layer 300 and the second encapsulant 32.

Next, example connection mechanisms between each of the first semiconductor die 100, the pattern 210, the UBM 220, the dielectric layer 300 and the solder ball 40 will be described in greater detail with reference to FIG. 3B.

The active layer 110, the at least one TSV 120 electrically connected to the active layer 110, and the bond pad 130 electrically connected to the at least one TSV 120 and exposed to one surface of the first semiconductor die 100 are formed on the first semiconductor die 100.

A passivation layer 310 may be formed on the first surface of the first semiconductor die 100 and may protect the first surface 100a of the first semiconductor die 100. For example, the bond pad 130 may be formed to be exposed to the outside from the passivation layer 310. The passivation layer 310 may comprise one or more insulating materials comprising an oxide, a nitride, and or a polyimide, for example. In addition, the passivation layer 310 may be formed by chemical etching, but aspects of the present disclosure are not limited thereto.

The pattern 210 may be electrically connected to the bond pad 130 and may comprise a redistribution layer (RDL) comprising a first seed layer 211 formed within the dielectric layer 300 and a first conductive layer 212 formed on the first seed layer 211.

The first seed layer 211 may be formed by sequentially depositing titanium and copper or by sequentially depositing a titanium-tungsten alloy and copper. The first seed layer 211 may function as a seed for forming the first conductive layer 212. For example, when the first seed layer 211 is formed by electroplating the first conductive layer 212, a path for the flow of current may be established, thereby allowing the first conductive layer 212 to be formed on the first seed layer 211.

The first conductive layer 212 may be formed on the first seed layer 211 by electroplating a copper layer, for example.

In addition, the UBM 220 may be electrically connected to the pattern 210 and may comprise a second seed layer 221 and a second conductive layer 222 formed on the second seed layer 221. The second seed layer 221 may be formed between the pattern 210 and the second conductive layer 222 to be described later. In detail, the second seed layer 221 may function as a seed for forming the second conductive layer 222. For example, when the second seed layer 221 is formed by electroplating, a path for the flow of current may be established, thereby allowing the second conductive layer 222 to be formed on the second seed layer 221. The second seed layer 221 may be formed by sequentially depositing titanium and copper or by sequentially depositing a titanium-tungsten alloy and copper, like the first seed layer 211.

The second conductive layer 222 may be formed between the second seed layer 221 and the solder ball 40.

The second conductive layer 222 is illustrated as a single conductive layer, but it may instead comprise multiple layers. The second conductive layer 222 may comprise nickel/silver (Ni—Au), chrome/chrome-copper alloy/copper (Cr/Cr—Cu/Cu), titanium-tungsten alloy/copper (Ti—W/Cu), aluminum/nickel/copper (Al/Ni/Cu), for example.

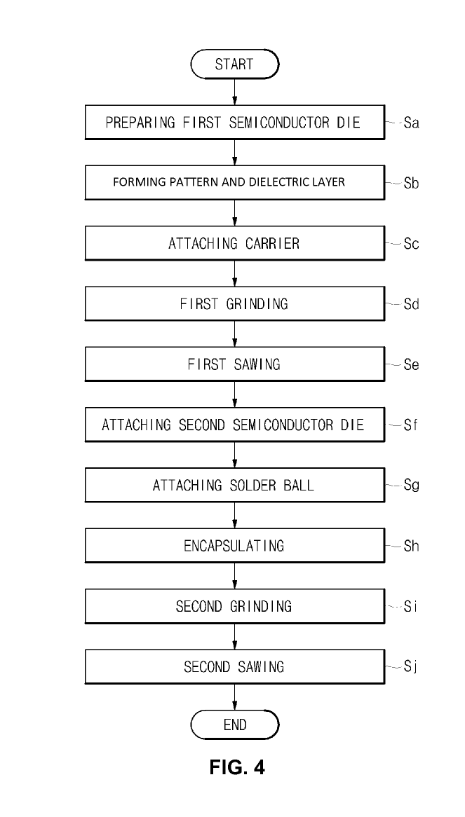

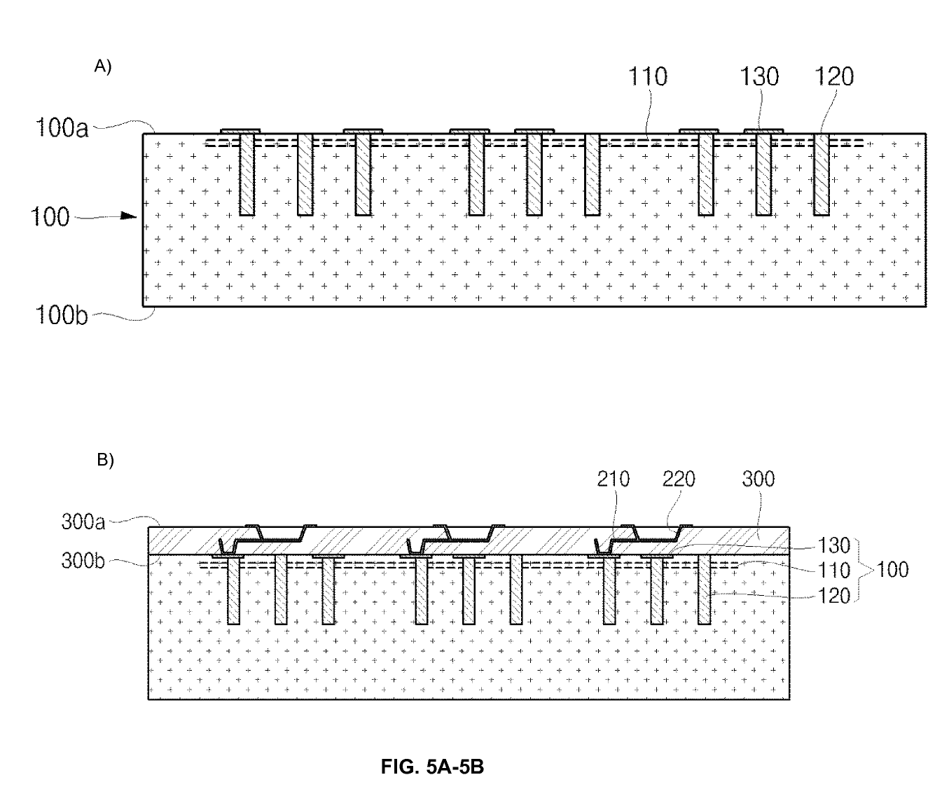

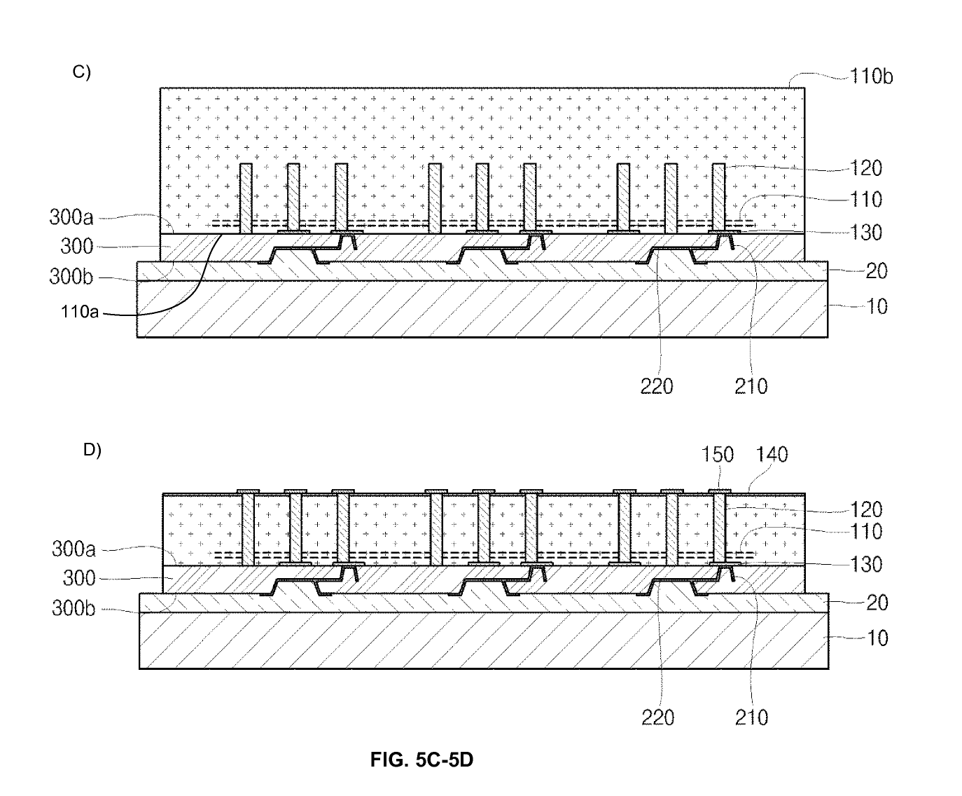

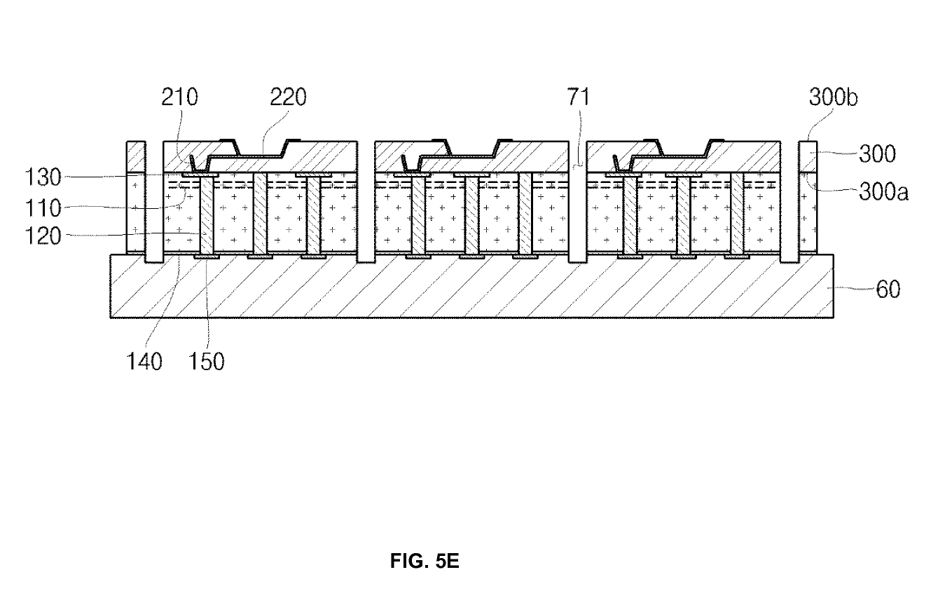

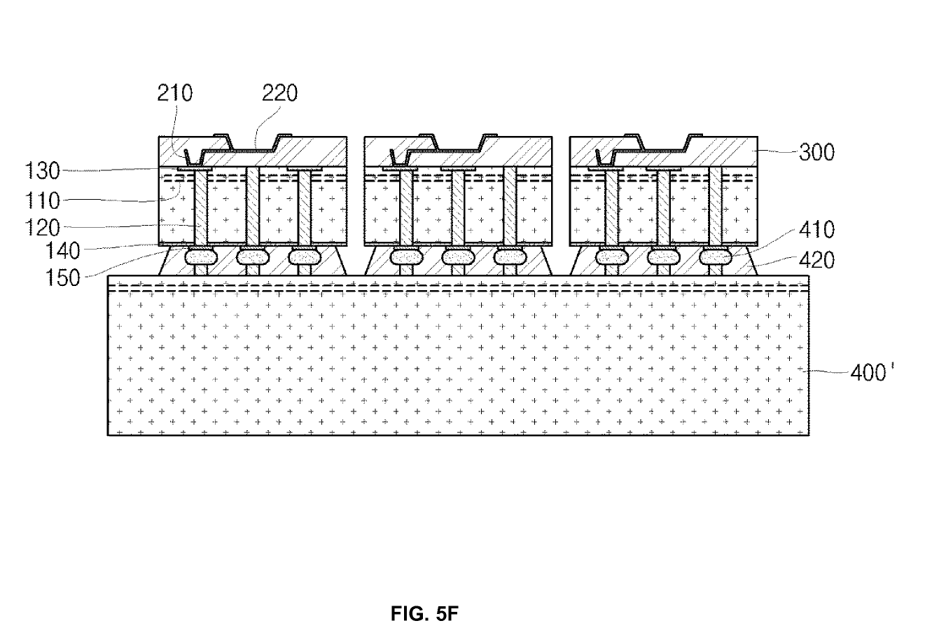

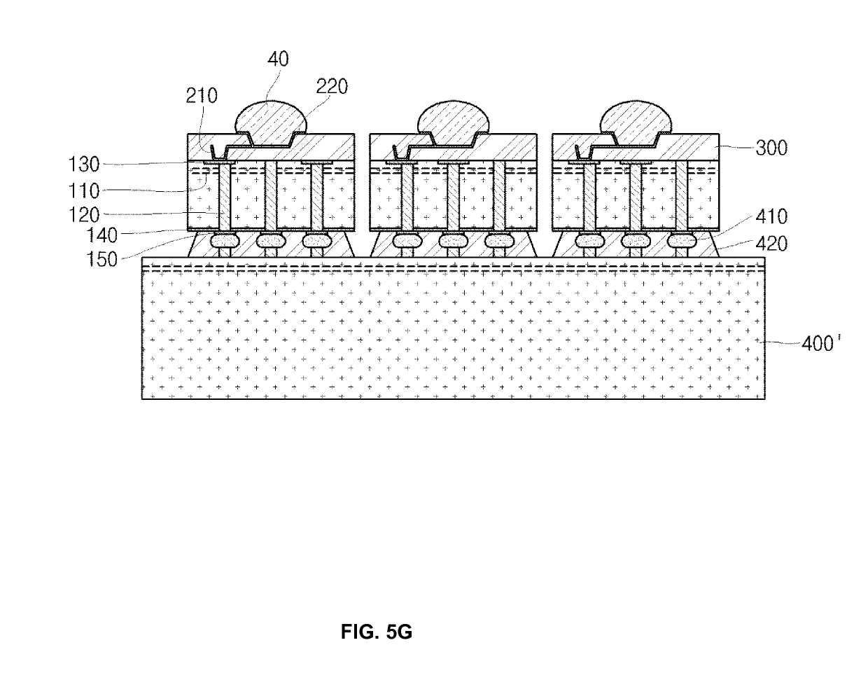

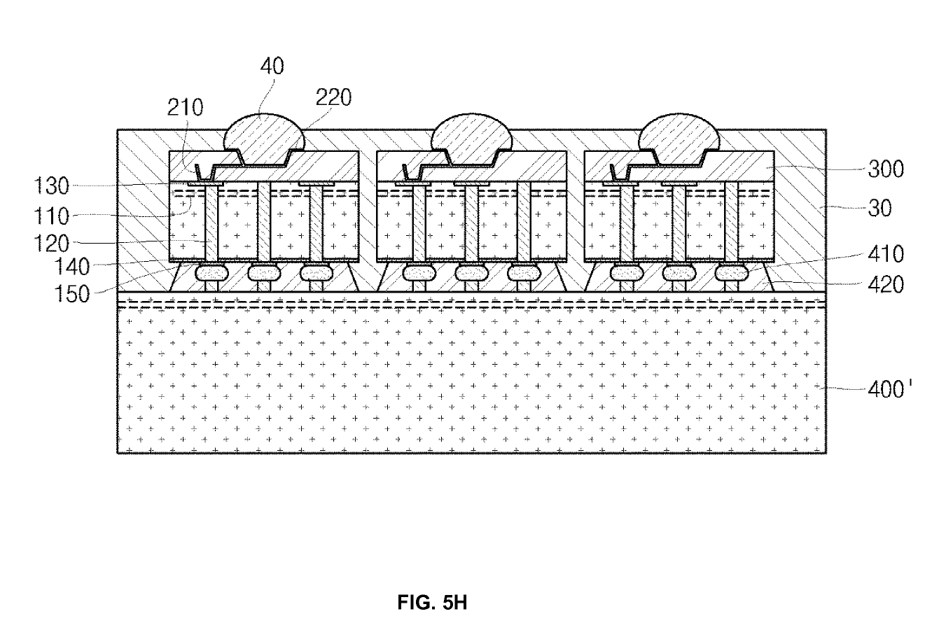

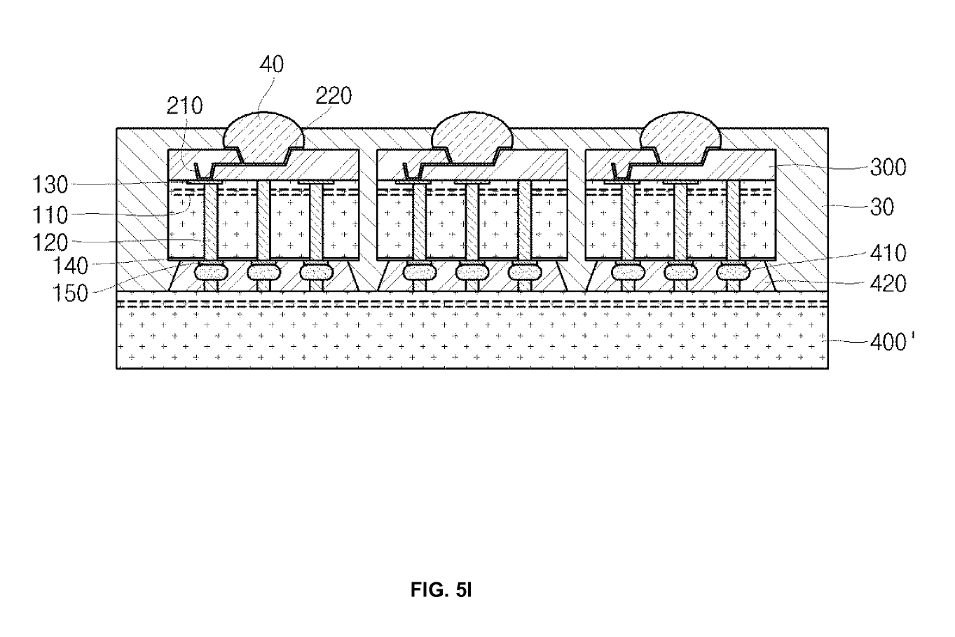

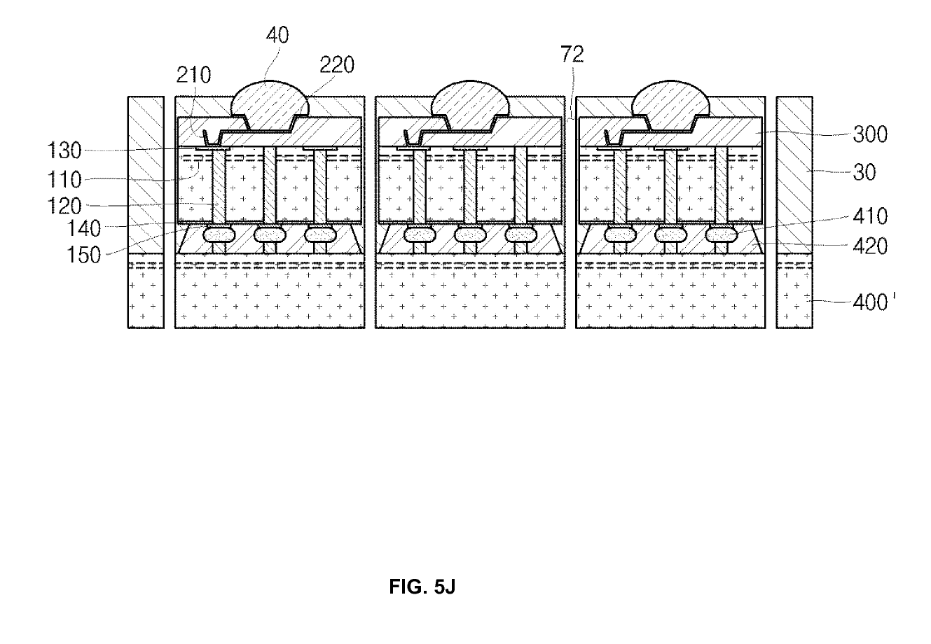

Next, a method for fabricating a semiconductor package according to another embodiment of the present disclosure will be described with reference to FIGS. 4 to 5J.

FIG. 4 is a flowchart of a method for fabricating a semiconductor package according to another embodiment of the present disclosure, and FIGS. 5A to 5J are cross-sectional views sequentially illustrating the method for fabricating a semiconductor package shown in FIG. 4.

Referring to FIG. 4, the method for fabricating a semiconductor package according to another embodiment of the present disclosure includes (Sa) preparing a first semiconductor die, (Sb) forming a pattern and a dielectric layer, (Sc) attaching the dielectric layer to a carrier, (Sd) first grinding, (Se) first sawing, (Sf) attaching a second semiconductor die to the first semiconductor die, (Sg) attaching a solder ball, (Sh) encapsulating, (Si) second grinding and (Sj) sawing.

As illustrated in FIG. 5A, in step (Sa), a first semiconductor die 100 may be prepared, the first semiconductor die 100 including an active layer 110, at least one through silicon via (TSV) 120 electrically connected to the active layer 110 and a bond pad 130 electrically connected to the TSV 120.

The first semiconductor die 100 may comprise substantially the same configuration with the first semiconductor die 100 shown in FIG. 2A and is denoted by the same reference numeral, and thus a detailed description thereof will be omitted.

As illustrated in FIG. 5B, in step (Sb), a pattern 210 and a dielectric layer 300 protecting the pattern 210 are formed on the first surface 100a of the first semiconductor die 100.

The pattern 210 and the dielectric layer 300 have substantially the same configurations as those shown in FIG. 2B and are denoted by the same reference numerals and detailed descriptions thereof will be omitted.

An under bump metallurgy (UBM) 220 electrically connected to the pattern 210 may be exposed to the outside of the dielectric layer 300.

As illustrated in FIG. 5C, in step (Sc), the carrier 10 may be attached and fixed to a first surface of the dielectric layer 300 and then transferred to a stage for performing each step. An adhesive layer 20 having an adhesive component may be formed between the first surface 300b of the dielectric layer 300 and the carrier 10.

As illustrated in FIG. 5D, in step (Sd), unnecessary portions of the first semiconductor die 100 may be removed by first grinding the second surface 110b of the first semiconductor die 100 by a predetermined thickness, thereby allowing the TSV 120 to be exposed. The first grinding may be performed using, for example, a diamond grinder for example, but aspects of the present disclosure are not limited thereto.

In step (Sd), an insulating layer 140 may be formed on the second surface 110b of the first semiconductor die 100 after the first grinding.

In addition, the bump pad 150, which may be connected to a conductive bump to be described later, may be formed on the exposed surface of the TSV 120 to be exposed from the insulating layer 140.

As illustrated in FIG. 5E, in step (Se), the first surface 110a or the second surface 110b of the first semiconductor die 100 may be attached to a dicing tape 60 and a sawing process may be performed on a sawing section 71 using sawing equipment (e.g., a blade) to separate the first semiconductor die 100 into individual units.

As illustrated in FIG. 5F, in step (Sf), a plurality of first semiconductor dies that may be produced from the first semiconductor die 100 may be attached to a second semiconductor die 400′ including an active layer. The second semiconductor die 400′ has a first surface that is substantially planar, and a second surface that is formed opposite to the first surface and may be substantially planar.

The second semiconductor die 400′ may, for example, be in the form of a bulk structure that is not separated into individual units, unlike the second semiconductor die 400 shown in FIG. 2E.

The second semiconductor die 400′ and the bump pad 150 of the first semiconductor die 100 may be electrically connected by a conductive bump 410 interposed there between. The conductive bump 410 may comprise one or more materials comprising a metal such as lead/tin (Pb/Sn) or leadless Sn, for example, but aspects of the present disclosure are not limited thereto.

The step (Sf) may be performed by a reflow process or a thermal compression process.

During the reflow process, the conductive bump 410 may be arranged between the bump pad 150 of the first semiconductor die 100 and the second semiconductor die 400′ to then passed through a chamber including a conveyor-like moving unit. A temperature high enough to melt the conductive bump 410 may be applied to an entrance of the chamber, and then the temperature may be slowly lowered to fuse and cure the conductive bump 410. Preferably, an underfill 420 may be filled between the first semiconductor die 100 and the second semiconductor die 400′, followed by curing. The underfill 420 may protect a bump adhesion part from external factors, such as mechanical impacts or corrosion, which may occur during the manufacture of the semiconductor package. The underfill 420 may comprise one or more materials comprising an epoxy thermocurable material, polyimide, polyurethane, a polymeric material, filled epoxy, a filled thermoplastic material, a filled thermocurable material, filled polyimide, filled polyurethane, a filled polymeric material, or a fluxed underfill, for example, but aspects of the present disclosure are not limited thereto.

During the thermal compression process, a nonconductive film (NCF) may be attached to the second semiconductor die 400′ and the conductive bump 410 may be then arranged between the bump pad 150 of the first semiconductor die 100 and the second semiconductor die 400′. Thereafter, a predetermined pressure may be applied to the second semiconductor die 400′ at a predetermined temperature or higher to fuse and cure the conductive bump 410. In order to lower a working temperature and to reduce a working time, ultrasonic waves may be employed with the thermal compression process.

As illustrated in FIG. 5G, in step (Sg), the solder ball 40 may be attached to the UBM 220.

The solder ball 40 may have a substantially similar configuration to the solder ball 40 shown in FIG. 21 and is denoted by the same reference numeral, and thus a detailed description thereof will be omitted.

As illustrated in FIG. 5H, in step (Sh), outer surfaces of the first semiconductor die 100, the dielectric layer 300 and the second semiconductor die 400′ may be encapsulated using an encapsulant 30.

The encapsulant 30 may encapsulate the first semiconductor die 100, the dielectric layer 300 and the second semiconductor die 400′, thereby protecting the same from external impacts or oxidation. The encapsulant 30 may comprise an epoxy compound performing encapsulation using a mold, a liquid encapsulant member performing encapsulation using a dispenser, and equivalents thereof, for example, but aspects of the present disclosure are not limited thereto.

A portion of the solder ball 40 may be exposed to the outside of the encapsulant 30 to be electrically connected to an external device.

As illustrated in FIG. 5I, in step (Si), unnecessary portions of the first semiconductor die 100 may be removed by second grinding the other surface of the second semiconductor die 400′ that is not attached to the first semiconductor die 100 by a predetermined thickness. The second grinding may be performed using a diamond grinder for example, like the first grinding, but aspects of the present disclosure are not limited thereto.

As illustrated in FIG. 5J, in step (Sj), a sawing process may be performed on a sawing section 72 using sawing equipment (e.g., a blade) to separate each of the second semiconductor die 400′ and the first semiconductor die 100 into individual units. The sawing section 72 may be a region between the first semiconductor dies 100 separated in step (Se), where the encapsulant 30 may be formed.

Accordingly, the semiconductor package fabricated by the method for fabricating the semiconductor package shown in FIG. 5J may have a substantially similar configuration to the semiconductor package fabricated by the method for fabricating the semiconductor package shown in FIG. 2M.

This disclosure provides example embodiments supporting the present disclosure. The scope of the present disclosure is not limited by these example embodiments. Numerous variations, whether explicitly provided for by the specification or implied by the specification, such as variations in structure, dimension, type of material and manufacturing process, may be implemented by one skilled in the art in view of this disclosure.

In an example embodiment of the disclosure, a method is disclosed for a semiconductor package with reduced thickness and may comprise providing a first semiconductor die with an active layer, a through-silicon via (TSV), and a pattern and an under bump metal (UBM) in a dielectric layer on the active layer. A carrier may be bonded to the dielectric layer and the UBM. The first semiconductor die may be thinned to expose the TSV at a second surface of the first semiconductor die. A bump pad may be formed on the exposed TSV and a second semiconductor die may be bonded to the bump pad.

The first semiconductor die, the second semiconductor die, and an outer surface of the dielectric layer may be encapsulated utilizing a first encapsulant. The carrier may be removed from the dielectric layer and the UBM, and a solder ball may be formed on the UBM. A groove may be formed through the dielectric layer and into the first semiconductor die. The groove may be filled and the dielectric layer and a portion of the solder ball may be encapsulated utilizing a second encapsulant.

The first semiconductor die may be separated into a plurality of units by sawing through the groove and the first and second encapsulants. The first encapsulant may be thinned such that it may be coplanar with a surface of the second semiconductor die. The first encapsulant may be thinned using a grinding process. The semiconductor package may have a thickness of 580 μm or less. The semiconductor die may be bonded to the bump pad using a non-conductive film in a thermal compression process. The semiconductor die may be bonded to the bump pad using a reflow process. The pattern may comprise a redistribution layer (RDL). The groove may be formed using a laser drilling process.

Embodiments of the present disclosure provide a method for fabricating a semiconductor package, which can miniaturize the semiconductor package, and a semiconductor package using the same.

Embodiments of the present disclosure also provide a method for fabricating a semiconductor package, which can remove a printed circuit board (PCB) and a conductive filler, and a semiconductor package using the same.

Embodiments of the present disclosure also provide a method for fabricating a semiconductor package, which can reduce a fabrication cost, and a semiconductor package using the same.

Embodiments of the present disclosure also provide a method for fabricating a semiconductor package, which is excellent in heat dissipation, and a semiconductor package using the same.

In accordance with the present disclosure, there is provided a method for fabricating a semiconductor package, the method including (A) preparing a first semiconductor die having an active layer and at least one through silicon via (TSV) electrically connected to the active layer, (B) forming a pattern electrically connected to the TSV and a dielectric layer protecting the pattern on one surface of the first semiconductor die, (C) attaching one surface of the dielectric layer to a carrier, (D) first grinding the other surface of the first semiconductor die to expose the TSV, (E) attaching at least one second semiconductor die to the other surface of the first semiconductor die to be electrically connected to the exposed TSV, (F) first encapsulating outer circumferential surfaces of the first semiconductor die, the dielectric layer and the second semiconductor die using a first encapsulant, and (G) removing the carrier and attaching a solder ball to be electrically connected to the pattern.

The pattern may be a redistribution layer (RDL). The dielectric layer may have a total thickness of 40 μm or less. The semiconductor package may have a thickness of 580 μm or less. In step (C), an adhesive layer may be interposed between the one surface of the dielectric layer and the carrier. In step (G), the adhesive layer may be removed. In step (E), at least one conductive bump may be formed between the second semiconductor die and the TSV, and the second semiconductor die may be electrically connected to the TSV through the conductive bump. In step (E), the second semiconductor die may be attached to the other surface of the first semiconductor die by a reflow process. In step (E), an underfill may be filled between the first semiconductor die and the second semiconductor die to then be cured. In step (E), a nonconductive film (NCF) may be attached to the second semiconductor die, and the second semiconductor die may be attached to the other surface of the first semiconductor die by a thermal compression process. An under bump metallurgy (UBM) exposed through the dielectric layer may be further formed on the RDL. The solder ball may be attached to the UBM by a reflow process. The method may further include (H) second grinding the first encapsulant to expose the other surfaces of a plurality of the second semiconductor dies.

When the second semiconductor die includes a plurality of second semiconductor dies, the method may further include (I) sawing the first semiconductor die and the dielectric layer for the first semiconductor die and the second semiconductor die is to be separated into individual units together. The step (I) may include (I1) pre-forming a laser drilling area from a sawing section of one surface of the dielectric layer to have a predetermined thickness, (I2) second encapsulating the one surface of the dielectric layer using a second encapsulant while exposing a portion of the solder ball, (I3) mounting the other surfaces of each of the plurality of second semiconductor dies on a dicing tape, and (I4) sawing the sawing section. The first encapsulant and the second encapsulant may be made from the same material. A reference point recognizing die may be formed in a portion of the first semiconductor die and one end of the reference point recognizing die may be exposed of the outside of the second encapsulant. In step (I), the sawing section may be set by recognizing coordinates of the reference point recognizing die.

In accordance with the present disclosure, there is provided a semiconductor package including a first semiconductor die having an active layer and at least one through silicon via (TSV) electrically connected to the active layer, a pattern formed on one surface of the first semiconductor die and electrically connected to the TSV, a dielectric layer protecting the pattern, a second semiconductor die electrically connected to the TSV and attached to the other surface of the first semiconductor die, a first encapsulant first encapsulating side surfaces of the second semiconductor die, a second encapsulant second encapsulating one surface of the dielectric layer, and a solder ball electrically connected to the pattern and exposed to the outside of the second encapsulant

The pattern may be a redistribution layer (RDL). The dielectric layer may have a total thickness of 40 μm or less. The semiconductor package may have a thickness of 580 μm or less. At least one conductive bump may be formed between the second semiconductor die and the TSV, and the second semiconductor die may be electrically connected to the TSV through the conductive bump. An underfill may be interposed between the first semiconductor die and the second semiconductor die. An under bump metallurgy (UBM) exposed through the dielectric layer may further be formed in the RDL, and the solder ball may be attached to the UBM. Side surfaces of the first semiconductor die may be exposed to the outside.

In accordance with the present disclosure, there is provided a method for fabricating a semiconductor package, the method including (a) preparing a first semiconductor die having an active layer and at least one through silicon via (TSV) electrically connected to the active layer, (b) forming a pattern electrically connected to the TSV and a dielectric layer protecting the pattern on one surface of the first semiconductor die, (c) attaching the one surface of the dielectric layer to a carrier, (d) first grinding the other surface of the first semiconductor die to expose the TSV, (e) sawing the first semiconductor die to separate into individual units, (f) attaching the separated first semiconductor die to a second semiconductor die to be electrically connected to the exposed TSV, (g) attaching a solder ball to the pattern to be electrically connected thereto, (h) encapsulating outer surfaces of the first semiconductor die, the dielectric layer and the second semiconductor die using an encapsulant, and (i) second grinding the other surface of the second semiconductor die that is not attached to the first semiconductor die.

The pattern may be a redistribution layer (RDL). The dielectric layer may have a total thickness of 40 μm or less. The semiconductor package may have a thickness of 580 μm or less. In step (F), at least one conductive bump may be formed between the second semiconductor die and the TSV, and the second semiconductor die may be electrically connected to the TSV through the conductive bump. In step (F), the first semiconductor die may be attached to the second semiconductor die by a reflow process. In step (F), an underfill may be filled between the first semiconductor die and the second semiconductor die to then be cured. An under bump metallurgy (UBM) exposed through the dielectric layer may further be formed in the RDL. The method may further include (j) sawing the encapsulant and the second semiconductor die to separate the second semiconductor die into individual units.

As described above, in the method for fabricating a semiconductor package and the using the same according to the embodiments of the present disclosure, the semiconductor package can be miniaturized. In addition, in the method for fabricating a semiconductor package and the using the same according to the embodiments of the present disclosure, a printed circuit board (PCB) and a conductive filler can be removed. In addition, in the method for fabricating a semiconductor package and the using the same according to the embodiments of the present disclosure, a fabrication cost can be reduced.

While various aspects of the present disclosure have been described with reference to certain supporting embodiments, it will be understood by those skilled in the art that various changes may be made and equivalents may be substituted without departing from the scope of the present disclosure. In addition, many modifications may be made to adapt a particular situation or material to the teachings of the present disclosure without departing from its scope. Therefore, it is intended that the present disclosure not be limited to the particular embodiments disclosed, but that the present disclosure will include all embodiments falling within the scope of the appended claims.

What is claimed is:

1. A method for manufacturing a semiconductor package, the method comprising:
providing a first semiconductor die with an active layer at a first surface, a through-silicon via (TSV), a dielectric layer on the active layer, and a pattern and an under bump metal (UBM) in the dielectric layer;
bonding a carrier to the dielectric layer and the UBM;
thinning the first semiconductor die to expose the TSV at a second surface of the first semiconductor die;
forming a bump pad on the exposed TSV;
bonding a second semiconductor die to the bump pad;
encapsulating the first semiconductor die, the second semiconductor die, and a and an outer surface of the dielectric layer utilizing a first encapsulant;
removing the carrier from the dielectric layer and the UBM;
forming a solder ball on the UBM;
forming a groove through the dielectric layer and into the first semiconductor die;
filling the groove and encapsulating the dielectric layer and a portion of the solder ball utilizing a second encapsulant; and
separating the first semiconductor die into a plurality of units by sawing through the groove and the first and second encapsulants.

2. The method according to claim 1, comprising thinning the first encapsulant such that it is coplanar with a surface of the second semiconductor die.

3. The method according to claim 2, wherein said thinning the first encapsulant comprises thinning the first encapsulant using a grinding process.

4. The method according to claim 1, wherein the semiconductor package has a thickness of 580 μm or less.

5. The method according to claim 1, wherein said bonding a second semiconductor die to the bump pad comprises bonding the second semiconductor die to the bump pad using a non-conductive film in a thermal compression process.

6. The method according to claim 1, wherein said bonding a second semiconductor die to the bump pad comprises bonding the second semiconductor die to the bump pad using a reflow process.

7. The method according to claim 1, wherein the pattern comprises a redistribution layer (RDL).

8. The method according to claim 1, wherein said forming the groove comprises forming the groove using a laser drilling process.

9. A method of manufacturing a semiconductor package, the method comprising:
providing a first semiconductor die with an active layer at a first surface, a through-silicon via (TSV), a dielectric layer on the active layer, and a pattern and an under bump metal (UBM) in the dielectric layer;
bonding a carrier to the dielectric layer and the UBM;
thinning the first semiconductor die to expose the TSV at a second surface of the first semiconductor die;
forming a bump pad on the exposed TSV;
sawing the first semiconductor die into at least a plurality of units;
removing the carrier from the dielectric layer and the UBM;
bonding the plurality of units to a first surface of a second semiconductor die comprising an active layer;
forming a solder ball on the UBM on each of the plurality of units;
encapsulating the plurality of units and the first surface of the second semiconductor die utilizing an encapsulant; and
sawing through the encapsulant and the second semiconductor die thereby forming packages, each of the packages comprising at least one of the plurality of units bonded to a respective portion of the second semiconductor die.

10. The method according to claim 9, comprising thinning the second semiconductor die before sawing through the second semiconductor die.

11. The method according to claim 10, wherein said thinning the second semiconductor die comprises thinning the second semiconductor die using a grinding process.

12. The method according to claim 9, wherein said bonding the plurality of units to a first surface of the second semiconductor die comprises bonding the plurality of units to the first surface of the second semiconductor die using a thermal compression process.

13. The method according to claim 9, wherein said bonding the plurality of units to a first surface of the second semiconductor die comprises bonding the plurality of units to the first surface of the second semiconductor die using a reflow process.

14. The method according to claim 9, wherein the pattern comprises a redistribution layer (RDL).

15. A semiconductor package, the device comprising:
a first semiconductor die with an active layer on a first surface, a through-silicon via (TSV) with a bump pad on a second surface opposite the first surface, a dielectric layer on the active layer, and a pattern and an under bump metal (UBM) in the dielectric layer;
a second semiconductor die comprising an active layer, wherein the first semiconductor die is bonded to the second semiconductor die using a conductive bump on the bump pad;
an encapsulant encapsulating a surface of the dielectric layer and at least a portion of the solder ball.

16. The device according to claim 15, wherein the semiconductor package has a thickness of 580 μm or less.

17. The device according to claim 15, wherein the pattern comprises a redistribution layer (RDL).

18. The device according to claim 15, wherein an underfill material is between the first semiconductor die and the second semiconductor die.

19. The device according to claim 15, wherein side surfaces of the first semiconductor die are exposed externally to the semiconductor package.

20. The device according to claim 15, wherein the dielectric layer has a total thickness of 40 μm or less.
